(19) United States
(12) Patent Application Publication
(10) Pub. No.: US 2008/0145702 A1
(43) Pub. Date: Jun. 19, 2008

(54) Phase change layers having different crystal lattices in single layer, methods of forming the same, phase change memory devices and methods of manufacturing the same

(75) Inventors: Woong-chul Shin, Suwon-si (KR); Ju-chul Park, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/000,380

(22) Filed: Dec. 12, 2007

(30) Foreign Application Priority Data
Dec. 15, 2006 (KR) 10-2006-0128940

(51) Int. Cl. B32B 9/04; H01L 47/00; G11C 11/00

(52) U.S. Cl. 428/698; 438/102; 365/163; 365/148; 257/E47.005

(57) ABSTRACT

A phase change material layer is a single layer including an upper layer portion and a lower layer portion. Crystal lattices of the upper layer portion and the lower layer portion are different. The phase change material layer is formed by forming a doped lower layer by supplying a first source with a doping gas to a substrate. The supply of the doping gas is stopped and an undoped upper layer is formed by supplying a second source onto the lower layer. The upper layer and the lower layer are formed such that crystal lattices of the upper and lower layers are different.

### PRIORITY STATEMENT

This non-provisional U.S. patent application claims priority under 35 U.S.C. §119 to Korean Patent Application No. 10-2006-0128940, filed on Dec. 15, 2006, in the Korean Intellectual Property Office, the entire contents of which is incorporated herein by reference.

### BACKGROUND

Description of the Conventional Art

Conventional phase change memories or phase change random access memories (PRAMs) include a storage node. A phase change layer and a transistor may be connected to the storage node. The state of the phase change layer may change from a crystalline state to an amorphous state, or vice versa, according to an applied voltage. For example, when the applied voltage is a set voltage, the phase change layer may change from the amorphous state to the crystalline state. When the applied voltage is a reset voltage, the phase change layer may change from the crystalline state to the amorphous state. One of the crystalline state and the amorphous state of the phase change layer corresponds to data 1 while the other corresponds to data 0.

The resistance of the phase change layer in the crystalline state may be less than the resistance of the phase change layer in the amorphous state. As a result, the current flowing through the phase change layer when the phase change layer is in the crystalline state may be larger than the current flowing through the phase change layer when in the amorphous state. Conventionally, data recorded in the phase change layer may be read by comparing a current measured when applying a read voltage to the phase change layer with a reference current.

In a conventional storage node, a titanium (Ti) layer and a titanium nitride (TiN) layer may be sequentially deposited on a phase change layer. The phase change layer may be a GST (Ge₂Sb₂Te₅) layer. The TiN layer may be used as a top electrode contact layer, whereas the Ti layer may be used as an adhesion layer to increase an adhesive force of the TiN layer.

As write operations and/or a read operations are repeated in conventional memory devices, however, Ti may diffuse from the Ti layer to the phase change layer. Accordingly, the composition and/or resistance of the phase change layer may change, thereby generating defects. For example, a set stuck fail and a reset stuck fail may occur as a result of the diffusion of Ti during an endurance test.

These defects may be reduced by removing the Ti layer or forming the Ti layer relatively thin. However, when the Ti layer is removed or formed relatively thin, micro lifting may occur between the phase change layer and the top electrode in the subsequent process. Micro lifting may increase parasitic resistance, which may increase reset current. These defects may reduce the reliability of the phase change memory.

As integration of conventional phase change memories increases, micro lifting between the phase change layer and the top electrode may be suppressed by increasing the adhesive force there between. Accordingly, although the Ti layer needs to be sufficiently thick, the Ti layer may not be sufficiently thick due to the above-discussed Ti diffusion. As a result, reliability and/or integration of conventional phase change memories may decrease.

### SUMMARY

Example embodiments relate to semiconductor memory devices, for example, phase change layers (also referred to herein as phase change material layers) having different crystal lattices in a single layer formed of the same or substantially the same material and methods of forming the same. Example embodiments also provide phase change memory devices having a Ti diffusion suppression layer, film or unit and methods of manufacturing the same.

Example embodiments provide phase change layers, which may suppress diffusion of impurities that may deteriorate characteristics of phase change layers from the upper deposition layer to the phase change layer. Example embodiments may also provide methods of forming the phase change layer.

At least one example embodiment provides a phase change material layer having a single layer divided into an upper layer portion and a lower layer portion. Crystal lattices of the upper layer portion and the lower layer portion may be different. The lower layer portion may be a chalcogenide material layer doped with impurities. The crystal lattice of the lower layer portion may be face-centered cubic (FCC). The upper layer portion may be an undoped chalcogenide material layer with a HCP crystal lattice.

According to at least one example embodiment, the lower layer portion may be any one of a Ge—Sb—Te layer, a Ge—Sb—Te—N layer, an As—Sb—Te—N layer, an As—Ge—Sb—Te—N layer, an Sn—Sb—Te—N layer, a (an element in Group 5A)-Sb—Te—N layer, a (an element in Group 6A)-Sb—Te—N layer, (an element in Group 5A)-Sb—Se—N layer, and an (an element in Group 6A)-Sb—Se—N layer, which are doped with nitrogen. The upper layer portion may be any one of a Ge—Sb—Te layer, an As—Sb—Te layer, an As—Ge—Sb—Te layer, an Sn—Sb—Te layer, a (an element in Group 5A)-Sb—Te layer, a (an element in Group 6A)-Sb—Te layer, (an element in Group 5A)-Sb—Se layer, and an (an element in Group 6A)-Sb—Se layer. The upper layer portion may be an undoped chalcogenide material layer.

At least one other example embodiment provides a method of forming a phase change material layer. According to at least this example embodiment, a doped lower layer may be formed by supplying a first source material with a doping gas to a substrate. The supply of the doping gas may be stopped, and an undoped upper layer may be formed by supplying a second source material onto the lower layer. The upper layer and the lower layer may be formed at a temperature for crystalline formation and crystal lattices of the upper and lower layers may be different.

According to at least some example embodiments, the first and second source materials may be the same or different. The lower and upper layers may be formed of a chalcogenide material layer, and may be formed at between about 250° C. and about 400° C., inclusive. The upper layer and the lower layer may be formed at different temperatures. The forming of the doped lower layer and the forming of the undoped upper layer may be performed in-situ.

At least one other example embodiment provides a phase change memory device. According to at least this example embodiment, the phase change memory may include a switching device and a storage node connected to the switching device. The storage node may include a lower stack, a phase change material layer and an upper stack deposited sequentially. The phase change material layer may be a single layer having an upper layer portion and a lower layer portion. The crystal lattices of the upper layer portion and the lower layer portion may be different.

At least one other example embodiment provides a phase change memory device including a switching device and a storage node connected to the switching device. The storage node may include a lower stack, a phase change material layer, a diffusion suppression film and an upper stack which may be sequentially deposited. The diffusion suppression film may be an undoped phase change material film. A crystal lattice of the diffusion suppression film may be different from the crystal lattice of the phase change material layer.

According to at least some example embodiments, the phase change material layer and the diffusion suppression film may be formed of a chalcogenide material. The crystal lattice of the phase change material layer may be FCC and the crystal lattice of the diffusion suppression film may be HCP. The upper stack may include an adhesive layer and a top electrode which may be sequentially deposited.

At least one other example embodiment provides a method of manufacturing a phase change memory device including a switching device and a storage node connected to the switching device. In at least this example embodiment, a lower stack, a phase change material layer and an upper stack may be formed sequentially. The phase change material layer may be formed by forming a doped lower layer by supplying a first source material with a doping gas onto a substrate. The supply of the doping gas may be stopped and an undoped upper layer may be formed by supplying a second source material onto the lower layer. The upper layer and the lower layer may be formed at a temperature for forming crystalline structures and crystal lattices of the upper and lower layers may be different.

In another example embodiment of a method of manufacturing a phase change memory device including a switching device and a storage node connected to the switching device, the storage node may be formed by sequentially forming a lower stack, a phase change material layer, a diffusion suppression film and an upper stack. The diffusion suppression film may be formed of an undoped phase change material film at a temperature for forming crystalline structures and to have a crystal lattice different from the crystal lattice of the phase change material layer.

### BRIEF DESCRIPTION OF THE DRAWINGS

Example embodiments will become more apparent by describing in detail the attached drawings in which:

FIG. 1 is a sectional view of a phase change layer formed of the single layer having different crystal lattices in the upper and lower layers thereof according to an example embodiment;

FIGS. 2 and 3 are sectional views showing a method of forming a phase change layer according to an example embodiment;

FIGS. 4 and 5 are example atomic force microscopic images showing the roughness of a surface of each of an upper layer P2 and a lower layer P1 of an example embodiment of a phase change layer when the layers are GST layers;

FIG. 6 is a graph showing example X-ray diffraction patterns of GST films doped with nitrogen which are formed between about 200° C. and about 400° C., inclusive;

FIG. 7 is a graph showing example X-ray diffraction patterns of normal (undoped) GST films formed at various temperatures;

FIG. 8 is a sectional view of a phase change memory device having a Ti diffusion suppression unit according to an example embodiment;

FIG. 9 illustrates a state of a phase change layer of a phase change memory device after applying a reset current;

FIG. 10 is a graph showing an example material ingredient distribution from the top electrode to the bottom electrode contact layer in the direction along a line 10-10′ of FIG. 9; and

FIGS. 11 through 13 are sectional views showing a method of manufacturing a phase change memory device according to an example embodiment.

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions are exaggerated for clarity.

Detailed illustrative example embodiments are disclosed herein. However, specific structural and functional details disclosed herein are merely representative for purposes of describing example embodiments. This invention may, however, may be embodied in many alternate forms and should not be construed as limited to only the example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items.

It will be understood that when an element or layer is referred to as being “formed on,” another element or layer, it can be directly or indirectly formed on the other element or layer. That is, for example, intervening elements or layers may be present. In contrast, when an element or layer is referred to as being “directly formed on,” to another element, there are no intervening elements or layers present. Other words used to describe the relationship between elements or layers should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Example embodiments of phase change layers having different crystal lattices in a single layer, methods of forming the same, phase change memory devices having a Ti diffusion suppression unit and methods of manufacturing the same are described in detail with reference to the accompanying drawings. In the drawings, the thicknesses of layers or regions are exaggerated for the clarity.

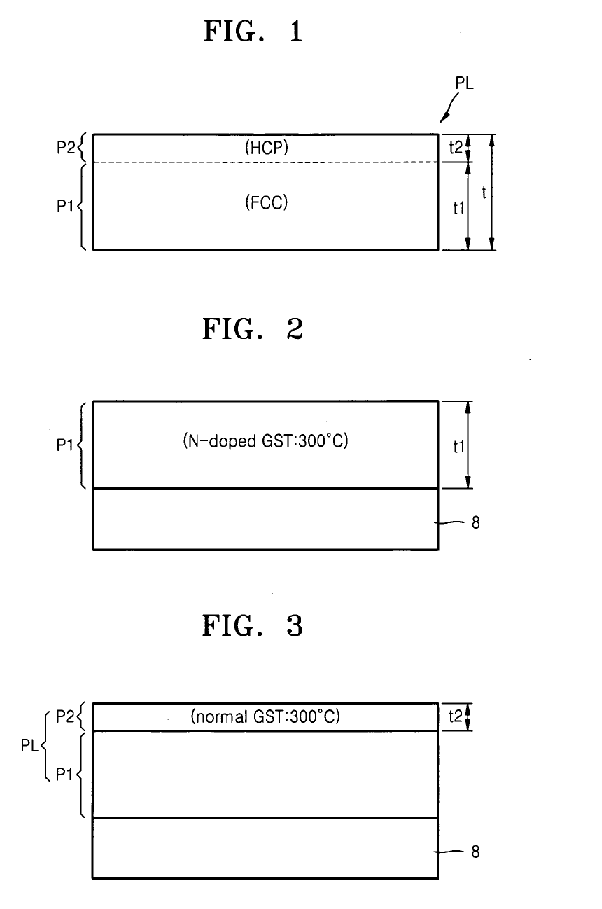

FIG. 1 is a sectional view of a phase change layer (also referred to herein as a phase change material layer) according to an example embodiment.

Referring to FIG. 1, a phase change layer PL may include a lower layer (or portion) P1 and an upper layer (or portion) P2. The lower layer P1 and the upper layer P2 may be formed sequentially. The thickness t1 of the lower layer P1 may be between about 10 nm and about 100 nm, inclusive. The thickness t2 of the upper layer P2 may be between about 5 nm and about 30 nm, inclusive. The thicknesses t1 and t2 may be adjusted when forming the phase change layer PL. The lower layer P1 and the upper layer P2 may differ in degree of doping, but may be formed of the same or substantially the same material. For example, the lower layer P1 may be a GST layer (e.g., Ge₂Sb₂Te₅ or the like) doped with nitrogen or the like, while the upper layer P2 may be a GST layer without impurities.

Because the lower and upper layers P1 and P2 are formed of the same or substantially the same material, the phase change layer PL may include a single layer. A boundary line between the lower and upper layers P1 and P2 in the drawing is shown for the sake of clarity and convenience of classification.

The crystal lattice of the lower layer P1 may be a face-centered cubic (FCC), while the crystal lattice of the upper layer P2 may be hexagonal close-packed (HCP).

The lower layer P1 may be a chalcogenide layer other than a GST layer, for example, a Ge—Sb—Te—N layer, an As—Sb—Te—N layer, an As—Ge—Sb—Te—N layer, an Sn—Sb—Te—N layer, a (an element in Group 5A)-Sb—Te—N layer, a (an element in Group 6A)-Sb—Te—N layer, (an element in Group 5A)-Sb—Se—N layer, and an (an element in Group 6A)-Sb—Se—N layer, which may be doped with impurities. In one example, the lower layer P1 may be a GST layer doped with impurities at a given concentration. For example, the lower layer P1 may be a GST layer doped with an impurity (e.g., nitrogen) concentration of about 2 wt %.

The upper layer P2 may be an undoped chalcogenide layer other than a GST layer. For example the upper layer P2 may be a Ge—Sb—Te layer, an As—Sb—Te layer, an As—Ge—Sb—Te layer, an Sn—Sb—Te layer, a (an element in Group 5A)-Sb—Te layer, a (an element in Group 6A)-Sb—Te layer, (an element in Group 5A)-Sb—Se layer, and an (an element in Group 6A)-Sb—Se layer.

FIGS. 2 and 3 are sectional views showing a method of forming a phase change layer according to an example embodiment.

Referring to FIG. 2, the lower layer P1 may be formed on a substrate 8 to a first thickness t1. The lower layer P1 may be a chalcogenide layer doped with impurities as described above with regard to FIG. 1. When the lower layer P1 is a GST layer doped with nitrogen, for example, the lower layer P1 may be formed by supplying a source material for GST deposition along with a doping nitrogen gas to the substrate 8. The source material for the GST deposition may be supplied using a sputtering deposition method, chemical vapor deposition (CVD), metal organic chemical vapor deposition (MOCVD) or the like. When using CVD or MOCVD, the source materials for GST layer may be supplied in form of a precursor.

In forming the lower layer P1, the doping concentration of nitrogen may be between about 1% and about 10%, inclusive. In one example, the doping concentration of nitrogen may be about 2%. The deposition temperature may be between about 250° C. and about 400° C., inclusive. In one example, the deposition temperature may be about 300° C. Such deposition processes may be performed until the first thickness t1 of the lower layer P1 is between about 10 nm and about 100 nm, inclusive. The crystal lattice of the lower layer P1 formed as discussed above may have a face-centered cubic (FCC) lattice, which will be described in more detail below.

Referring to FIG. 3, the upper layer (or portion) P2 may be formed on the lower layer (or portion) P1 to a second thickness t2. The upper layer P2 may be formed of the undoped chalcogenide material described with regard to FIG. 1. The upper layer P2 may be formed in the same or substantially the same manner as the lower layer P1, except that a doping gas may not be supplied when forming the upper layer P2. According to at least this example embodiment, after the lower layer P1 is formed to the first thickness t1, the process may be continued in-situ, by stopping the supply of a doping gas, while other process conditions are maintained. Because the process after the doping gas supply is stopped may form the upper layer P2, the process may continue until the upper layer P2 of the second thickness t2. According to at least this example embodiment, the process for forming the lower layer P1 and the upper layer P2 may be one continuous process, or alternatively, two separate processes forming a single layer.

As shown in FIG. 3, the undoped chalcogenide material may be deposited on the lower layer P1. The crystal lattice of the upper layer P2 formed as described above may be different from the lower layer P1. For example, the crystal lattice of the upper layer P2 may be an HCP, which will be described in more detail below.

When the upper layer P2 is a GST layer (e.g., a normal GST layer), for example, the upper layer P2 may be formed by continuing the process of forming the lower layer after the lower layer P1 is formed, but without the supply of the doping (e.g., nitrogen) gas. This process may continue until the upper layer P2 having a thickness of between about 5 nm and about 30 nm, inclusive, is formed on the lower layer P1. Through the above process, the single phase change layer PL in which the crystal lattices in the upper and lower portions are different may be formed on the substrate 8.

In another example embodiment, the lower layer P1 and the upper layer P2 may be formed in the above-described continuous in-situ process by varying the temperature at which the lower and upper layers P1 and P2 are formed. In this example, the formation temperatures of the lower layer P1 and the upper layer P2 may be set such that the crystal lattice of the lower layer P1 is formed as a FCC and the crystal lattice of the upper layer P2 is formed as a HCP. For example, when the phase change layer PL is a GST layer, the lower layer P1 may be formed according to the above-described process conditions. The upper layer P2 may be formed according to the above-described process conditions for the lower layer P1, but at a temperature different from that of the lower layer P1 within a range of about 250° C. to about 400° C., inclusive. For example, the upper layer P2 may be formed at a temperature of about 180° C. or about 250° C., and without supplying the doping gas.

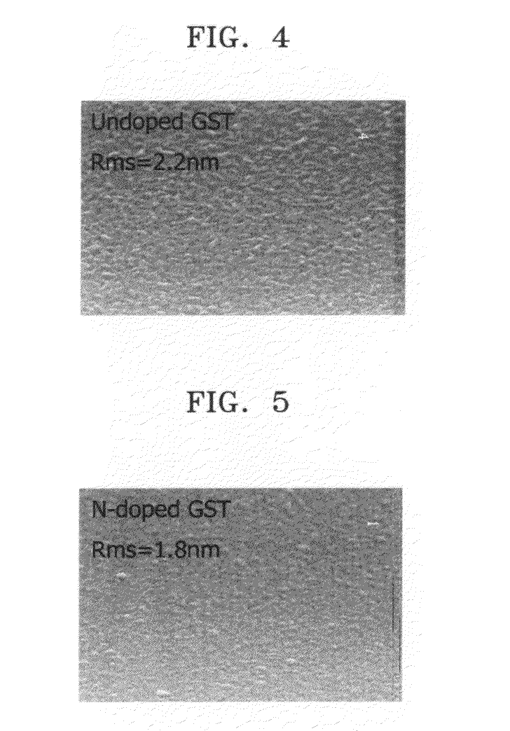

FIGS. 4 and 5 are example atomic force microscopic images showing the roughness of surface of each of the upper layer P2 and the lower layer P1 when the layers P1 and P2 are GST layers. As shown in FIGS. 4 and 5, there is no significant difference in the surface roughness between the upper layer P2 and the lower layer P1. In this example, the surface roughness of the upper layer P2 in FIG. 4 is about 2.2 nm while that of the lower layer P1 of FIG. 5 is about 1.8 nm. The difference in the surface roughness between the upper and lower layers P2 and P1 is about 0.4 nm. Thus, there is relatively little difference in morphology between the phase change layers of unit cells formed of the upper layer P2 and the lower layer P1.

FIG. 6 is a graph showing example X-ray diffraction patterns of GST films doped with nitrogen and formed at about 200° C. and about 400° C., respectively. As shown in FIG. 6, all crystal peaks of X-ray diffraction patterns G1 and G2 of the GST film doped with nitrogen formed at respective temperatures of about 200° C. and about 400° C. coincide. The X-ray diffraction patterns G1 and G2 indicate that the GST film doped with nitrogen formed at about 200° C. and about 400° C. have a FCC crystal lattice structure.

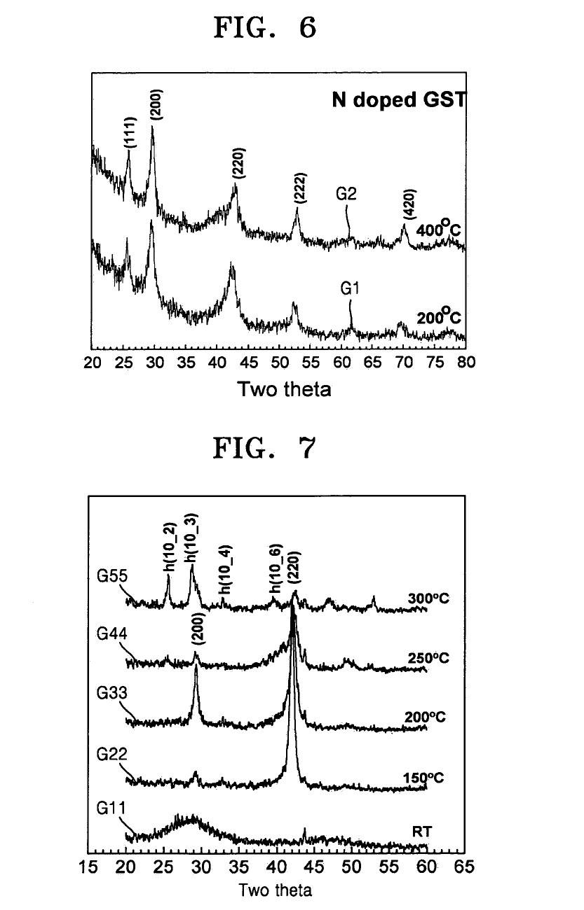

FIG. 7 is a graph showing example X-ray diffraction patterns of normal (undoped) GST films formed at various temperatures. Referring to FIG. 7, peaks (hereinafter, referred to as the first peak) appearing in X-ray diffraction patterns G22 and G33 of the normal GST films formed at temperatures about 150° C. and about 200° C., respectively, are mainly generated on the crystal surfaces (200) and (220). This signifies that the crystal lattices of the normal GST films formed at about 150° C. and about 200° C. are FCC.

As further shown in FIG. 7, the peaks (hereinafter, referred to as the second peak) appearing in X-ray diffraction patterns G44 and G55 of the normal GST films formed at temperatures of about 250° C. and about 300° C., respectively, are different from the first peak. The second peak is the same as the peak generated when the crystal lattice of the normal GST film is HCP. Thus, as shown in FIG. 7, when the normal GST film is formed at about 250° C. and about 300° C., the crystal lattice may be HCP. In FIG. 7, there is relatively little crystal peak in the X ray diffraction pattern G11 of the normal GST film formed at about room temperature. This result signifies that the GST film formed at room temperature (e.g., a temperature lower than about 150° C.) may be amorphous and may not have a crystal lattice.

As shown in FIGS. 6 and 7, in methods according to example embodiments, the first layer P1 of the phase change layer PL formed at about 300° C. may be a GST layer doped with nitrogen and may have an FCC crystal lattice. The second layer P2 of the phase change layer PL formed at about 300° C. may be a normal GST layer having an HCP crystal lattice.

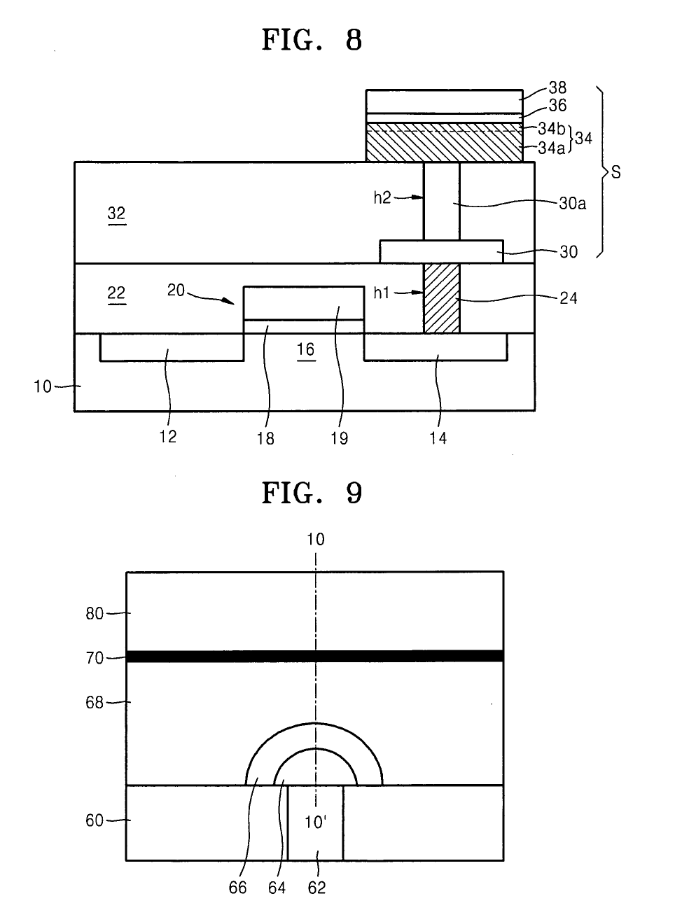

FIG. 8 is a sectional view illustrating a phase change memory device having a Ti diffusion suppression (e.g., prevention) unit according to an example embodiment. Referring to FIG. 8, first and second impurity regions 12 and 14 may be formed on a substrate 10. The first and second impurity regions 12 and 14 may be separated from each other on the substrate 10. The first and second impurity regions 12 and 14 may be formed by doping the substrate with a conductive impurity, such as, nitrogen or the like. One of the first and second impurity regions 12 and 14 may be a source and the other may be drain.

A gate stack 20 may be formed on the substrate 10 between the first and second impurity regions 12 and 14. A channel area 16 may be formed under the gate stack 20 between the first and second impurity regions 12 and 14. The gate stack 20 may include a gate insulation film 18 and a gate electrode 19. The insulation film 18 and the gate electrode 19 may be stacked sequentially. The portion of the substrate 10 on which the first and second impurity regions 12 and 14 are formed along with the gate stack 20 forms a transistor.

A first insulating interlayer 22 may be formed on the substrate 10. The first insulating layer 22 may cover the transistor. A first contact hole h1 may be formed in the first insulating interlayer 22. The first contact hole h1 may expose at least a portion of a surface of the second impurity region 14. The first contact hole hi may be filled with a conductive plug 24. A bottom electrode 30 may be formed on the first insulating interlayer 22. The bottom electrode 30 may cover the exposed surface of the conductive plug 24 in the first contact hole h1. A second insulating interlayer 32 may be deposited on the first insulating interlayer 22. The second insulating interlayer 32 may cover the bottom electrode 30. A second contact hole h2 may be formed in the second insulating interlayer 32. The second contact hole h2 may expose a portion of the bottom electrode 30.

The second contact hole h2 may be filled with a bottom electrode contact layer 30a. The bottom electrode 30 and the bottom electrode contact layer 30a may form a lower stack. The bottom electrode contact layer 30a may be a conductive material layer such as TiN, TiAlN or the like. The second insulating interlayer 32 may be the same or substantially the same material layer as the first insulating interlayer 22. A phase change layer 34 covering the exposed surface of the bottom electrode contact layer 30a may be formed on the second insulating interlayer 32. An adhesive layer 36 and a top electrode 38 may be deposited sequentially on the phase change layer 34. The adhesive layer 36 and the top electrode 38 may form an upper stack. The adhesive layer 36 may be a Ti layer or the like and the top electrode 38 may be a TiN electrode or the like. The lower stack, the phase change layer 34 and the upper stack may constitute a storage node S.

The phase change layer 34 may include a lower layer (or portion) 34a and an upper layer (or portion) 34b. The lower layer 34a and the upper layer 34b may be formed sequentially. The phase change layer 34 may be the same or substantially the same as the phase change layer PL described above with regard to FIG. 1. Thus, the lower layer 34a and the upper layer 34b may be the same or substantially the same as the lower layer P1 and the upper layer P2, respectively. The crystal lattice of the lower layer 34a may be FCC while the crystal lattice of the upper layer 34b may be HCP. The other specifications and/or characteristics of the lower layer 34a and the upper layer 34b may be the same or substantially the same as those of the lower layer P1 and the upper layer P2, respectively.

FIG. 9 illustrates the state (or phase) of a phase change layer 68 of the phase change memory device after a reset current is applied. As shown in FIG. 9, a first region 64 of the phase change layer 68 covering the upper surface of the bottom electrode contact layer 62 may be amorphous. The first region 64 may be an area in which the phase may change from a crystalline state to an amorphous state due to heat generated by the reset current. The heat generated by the reset current may be transferred to another area of the phase change layer 68 via the first region 64. The amount of heat transferred to the outside of the first region 64 may not be sufficient to change the state of the phase change layer 68 to be amorphous, but may be sufficient to change the crystal lattice of the phase change layer 68. Accordingly, the phase of a partial region 66 surrounding the first region 64 of the phase change layer 68 (hereinafter, referred to as the second region) may not become amorphous, but the crystal lattice may change from FCC to HCP.

In addition, the amount of heat transferred to the outside of the second region 66 of the phase change layer 68 may not be sufficient to change the crystal lattice. Thus, the phase and crystal lattice of the area except for the first and second regions 64 and 66 of the phase change layer may maintain the same crystalline state and FCC lattice structure as before the reset current is applied. In FIG. 9, an insulating interlayer 60, an adhesive layer (Ti layer) 70 and a top electrode 80 are shown.

FIG. 10 is a graph showing an example material ingredient distribution from the top electrode 80 to the bottom electrode contact layer 62 in the direction along a line 10-10′ of FIG. 9. The graph of FIG. 10 is illustrated using the upper surface of the top electrode 80 as a reference point. In FIG. 10, first through fifth graphs C1-C5 indicate the distributions of Ti, W, Te, Sb and Ge respectively. First through fifth sections T1-T5 correspond to an area including the top electrode 80 and the Ti adhesive layer 70, an area between the second region 66 of the phase change layer 68 and the Ti adhesive layer 70, the second region 66 of the phase change layer 68, the first region 64 of the phase change layer 68 and the bottom electrode contact layer 62 respectively.

In FIG. 10, as shown in the first graph C1, although it may be a relatively small amount, Ti may be distributed between the second through fourth sections T2-T4. As a result, the Ti of the adhesive layer 70 may diffuse downward. As is further shown in FIG. 10, Ti may be distributed the most in the first section T1 and reduced near the beginning of the second section T2. At the beginning of the third section T3 corresponding to the second region 66 of the phase change layer 68, Ti may be reduced again. Accordingly, the distribution of Ti in the first region 64 of the phase change layer 68 (e.g., the amorphous area) may be reduced (e.g., become relatively small). As is shown by FIG. 10, the presence of the third section T3 may suppress the diffusion of Ti. The third section T3 may be an area in which the second region 66 of the phase change layer 68 is located. The difference between the second region 66 and other areas of the phase change layer 68 may be that the crystal lattice of the second region 66 is HCP. As a result, a phase change layer having a HCP crystal lattice may be used as a barrier layer suppressing and/or preventing diffusion of Ti.

Considering that the crystal lattice of the upper layer 34b in the phase change layer 34 of phase change memory devices according to example embodiments is HCP, the upper layer 34b may function as a barrier layer suppressing and/or preventing diffusion of impurities (e.g., Ti) from the material layer formed on the upper layer 34a. For example, the upper layer 34b may function as a barrier layer suppressing and/or preventing diffusion of impurities (e.g., Ti) from the adhesive layer 36 to the phase change layer 34.

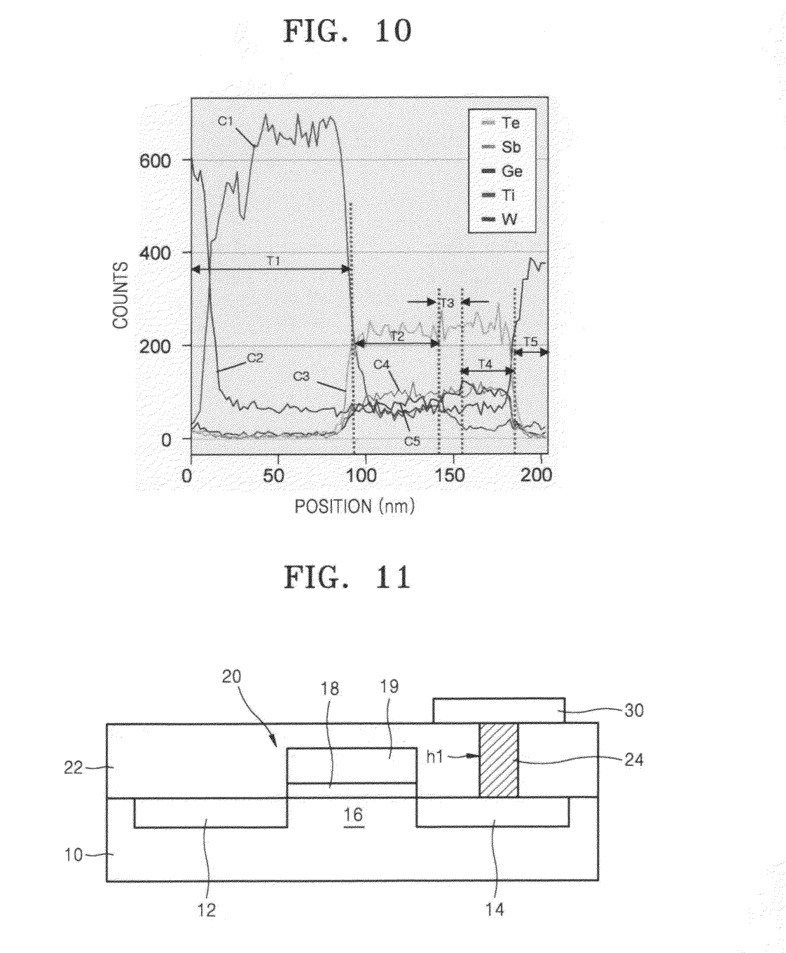

A method of manufacturing a phase change memory device according to an example embodiment will now be described with regard to FIGS. 11-13.

Referring to FIG. 11, the gate stack 20 may be formed on a given area of the substrate 10. The gate stack 20 may be formed by sequentially depositing the gate insulation film 18 and the gate electrode 19 on the substrate 10. A conductive impurity may be ion-injected into the substrate 10 using the gate stack 20 as a mask. The conductive impurity may be, for example, an n-type impurity. As a result of injecting the conductive impurity, the first and second impurity regions 12 and 14 may be formed in or on the substrate 10 at opposite sides of the gate stack 20. According to at least this example embodiment, one of the first and second impurity regions 12 and 14 may be a source, while the other may be a drain. The first and second impurity regions 12 and 14 and the gate stack 20 may constitute a transistor also referred to as a switching device. An area under the gate insulation film 18 of the substrate 10 between the first and second impurity regions 12 and 14 may be referred to as a channel area 16.

The first insulating interlayer 22 may be formed on the substrate 10. The first insulating interlayer 22 may cover the transistor. The first insulating interlayer 22 may be formed of a dielectric material such as SiOx, SiOxNy or the like. The first contact hole h1 may be formed in the first insulating interlayer 22. The first contact hole h1 may expose at least a portion of the second impurity region 14. The conductive plug 24 may be formed by filling the first contact hole h1 with a conductive material. The bottom electrode 30 may be formed on the first insulating interlayer 22. The bottom electrode 30 may cover the exposed surface of the conductive plug 24. The bottom electrode 30 may be formed of TiN, TiAlN or the like. Also, the bottom electrode 30 may be formed of silicide including any one selected from a group of metal ions including Ag, Au, Al, Cu, Cr, Co, Ni, Ti, Sb, V, Mo, Ta, Nb, Ru, W, Pt, Pd, Zn, Mg a combination thereof or the like. The bottom electrode 30 may be formed using CVD, ALD, a heat treatment by metal ion injection or the like, but example embodiments are not limited thereto.

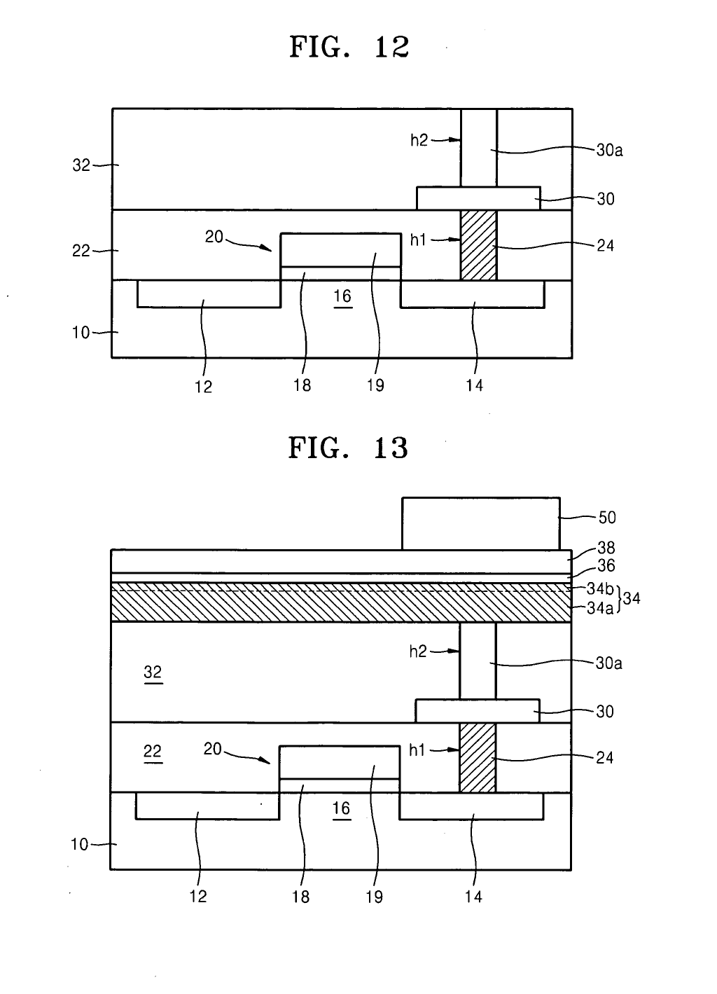

Referring to FIG. 12, the second insulating interlayer 32 may be formed on the first insulating interlayer 22. The second insulating interlayer 32 may cover the bottom electrode 30. The second insulating interlayer 32 may be formed of a dielectric material such as SiOx, SiOxNy or the like. The second contact hole h2 exposing a portion of the upper surface of the bottom electrode 30 may be formed in the second insulating interlayer 32. The bottom electrode contact layer 30a may be formed by filling the second contact hole h2 with TiN, TiAlN or the like.

Referring to FIG. 13, the phase change layer 34 may be formed on the second insulating interlayer 32. The phase change layer 34 may cover the upper surface of the bottom electrode contact layer 30a. The adhesive layer 36 and the top electrode 38 may be deposited sequentially on the phase change layer 34. The phase change layer 34 may be formed by depositing (e.g., sequentially depositing) the lower layer 34a and the upper layer 34b on the second insulating interlayer 32. The phase change layer 34 may be the same or substantially the same as the phase change layer PL of FIG. 1. Thus, the lower layer 34a and the upper layer 34b may be formed using example embodiments of methods of forming the lower layer P1 and the upper layer P2 described above with regard to FIGS. 2 and 3. The lower layer 34a and the upper layer 34b may be formed of the same or substantially the same materials forming the lower layer P1 and the upper layer P2, respectively.

After forming the top electrode 38, a photoresist pattern 50 may be formed on the top electrode 38. The photoresist patter 50 may define the area in which the storage node S of FIG. 8 may be formed. The top electrode 38, the adhesive layer 36, and the phase change layer 34 may be etched (e.g., sequentially etched) using the photoresist pattern 50 as an etch mask. The photoresist pattern 50 may be removed to form an example embodiment of a phase change memory device.

According to example embodiments, instead of forming the phase change layer 34 as a single layer including the upper layer 34b functioning as a diffusion suppression (e.g., prevention) layer, the phase change layer 34 may be formed with the lower layer 34a and a diffusion suppression film may be formed between the phase change layer 34 and the adhesive layer 36. The diffusion suppression film may be formed to be the same or substantially the same as the above-described upper layer 34b.

Although not described in detail herein for the sake of brevity, the structure of the storage node may be modified while maintaining the upper layer 34b as described above or separating the upper layer 34b from the phase change layer 34. Alternatively, a bottom electrode contact layer may more directly contact the transistor without passing through the bottom electrode and/or the conductive plug. Although discussed herein as being formed of the same or substantially the same phase change materials, the upper and lower layers of the phase change layer may be formed of different phase change materials.

In phase change memory devices according to example embodiments, the phase change layer may be a single layer including upper and lower layers. The upper and lower layers may be formed of the same or substantially the same phase change material. The upper layer may be a phase change material layer having an HCP crystal lattice, whereas the lower layer may have a FCC crystal lattice.

Alternatively, in example embodiments, the phase change layer may be formed with only the lower layer having a FCC crystal lattice, and a phase change material layer having a HCP crystal lattice may be formed separately as a diffusion suppression layer or film between the phase change layer and the adhesive layer.

Thus, phase change memory devices according to example embodiments may include a diffusion suppression film in the phase change layer itself or between the phase change layer and the upper structure thereof. Such a diffusion suppression film may reduce and/or prevent the diffusion of Ti from the adhesive layer including Ti to the phase change layer.

As described above, phase change memory devices according to example embodiments may suppress, reduce and/or prevent the diffusion of Ti to the phase change layer which may reduce defects in phase change layers. Because the diffusion suppression film is provided, the adhesive layer having a sufficient thickness may be formed between the phase change layer and the top electrode. Thus, the adhesive force between the phase change layer and the top electrode may increase as integration of phase change memory devices increases. Accordingly, the occurrence of micro lifting on a boundary surface between the phase change layer and the top electrode may be suppressed and/or prevented.

According to example embodiments, but contrary to the conventional art, a reset current need not be increased in phase change memory devices. Therefore, memory devices according to example embodiments may be operated with a given or desired reset current so that the operation reliability of the memory device may improve, and/or a degree of integration of the memory device may increase.

In example embodiments, the phase change material film may include chalcogenide alloys such as germanium-antimony-tellurium (Ge—Sb—Te), arsenic-antimony-tellurium (As—Sb—Te), tin-antimony-tellurium (Sn—Sb—Te), or tin-indium-antimony-tellurium (Sn—In—Sb—Te), arsenic-germanium-antimony-tellurium (As—Ge—Sb—Te). Alternatively, the phase change material film may include an element in Group VA-antimony-tellurium such as tantalum-antimony-tellurium (Ta—Sb—Te), niobium-antimony-tellurium (Nb—Sb—Te) or vanadium-antimony-tellurium (V—Sb—Te) or an element in Group VA-antimony-selenium such as tantalum-antimony-selenium (Ta—Sb—Se), niobium-antimony-selenium (Nb—Sb—Se) or vanadium-antimony-selenium (V—Sb—Se). Further, the phase change material film may include an element in Group VIA-antimony-tellurium such as tungsten-antimony-tellurium (W—Sb—Te), molybdenum-antimony-tellurium (Mo—Sb—Te), or chrome-antimony-tellurium (Cr—Sb—Te) or an element in Group VIA-antimony-selenium such as tungsten-antimony-selenium (W—Sb—Se), molybdenum-antimony-selenium (Mo—Sb—Se) or chrome-antimony-selenium (Cr—Sb—Se).

Although the phase change material film is described above as being formed primarily of ternary phase-change chalcogenide alloys, the chalcogenide alloy of the phase change material could be selected from a binary phase-change chalcogenide alloy or a quaternary phase-change chalcogenide alloy. Example binary phase-change chalcogenide alloys may include one or more of Ga—Sb, In—Sb, In—Se, Sb₂—Te₃ or Ge—Te alloys; example quaternary phase-change chalcogenide alloys may include one or more of an Ag—In—Sb—Te, (Ge—Sn)—Sb—Te, Ge—Sb—(Se—Te) or Te₈₁—Ge₁₅—Sb₂—S₂ alloy, for example.

In an example embodiment, the phase change material film may be made of a transition metal oxide having multiple resistance states, as described above. For example, the phase change material may be made of at least one material selected from the group consisting of NiO, TiO₂, HfO, Nb₂O₅, ZnO, WO₃; and CoO or GST (Ge₂Sb₂Te₅) or PCMO(PrₓCa₁-xMnO₃). The phase change material film may be a chemical compound including one or more elements selected from the group consisting of S, Se, Te, As, Sb, Ge, Sn, In and Ag.

While example embodiments have been particularly shown and described with reference to those illustrated in the drawings, it will be understood by those skilled in the art that various changes in form and details may be made therein without departing from the spirit and scope of the present invention as defined by the appended claims.

What is claimed is:

1. A phase change material layer, comprising:
a single layer including an upper layer portion and a lower layer portion, crystal lattices of the upper layer portion and the lower layer portion being different.

2. The phase change material layer of claim 1, wherein the lower layer portion is a chalcogenide material layer doped with impurities.

3. The phase change material layer of claim 2, wherein the lower layer portion is one selected from the group consisting of a Ge—Sb—Te layer, a Ge—Sb—Te—N layer, an As—Sb—Te—N layer, an As—Ge—Sb—Te—N layer, an Sn—Sb—Te—N layer, a (an element in Group 5A)-Sb—Te—N layer, a (an element in Group 6A)-Sb—Te—N layer, (an element in Group 5A)-Sb—Se—N layer and an (an element in Group 6A)-Sb—Se—N layer, which are doped with nitrogen.

4. The phase change material layer of claim 2, wherein the upper layer portion is an undoped chalcogenide material layer.

5. The phase change material layer of claim 1, wherein the crystal lattice of the lower layer portion is face-centered cubic (FCC) crystal lattice.

6. The phase change material layer of claim 1, wherein the upper layer portion is an undoped chalcogenide material layer.

7. The phase change material layer of claim 6, wherein the upper layer portion is one selected from the group consisting of a Ge—Sb—Te layer, an As—Sb—Te layer, an As—Ge—Sb—Te layer, an Sn—Sb—Te layer, a (an element in Group 5A)-Sb—Te layer, a (an element in Group 6A)-Sb—Te layer, (an element in Group 5A)-Sb—Se layer and an (an element in Group 6A)-Sb—Se layer.

8. The phase change material layer of claim 1, wherein the crystal lattice of the upper layer portion is hexagonal close-packed (HCP) crystal lattice.

9. A phase change memory device comprising:
a switching device; and
a storage node connected to the switching device, the storage node including,
a lower stack,
the phase change material layer of claim 1, and
an upper stack, wherein
the lower stack, the phase change material layer and the upper stack are sequentially deposited.

10. The phase change memory device of claim 9, wherein the lower layer portion is a chalcogenide material layer doped with impurities.

11. The phase change memory device of claim 10, wherein the lower layer portion is one selected from the group consisting of a Ge—Sb—Te layer, a Ge—Sb—Te—N layer, an As—Sb—Te—N layer, an As—Ge—Sb—Te—N layer, an Sn—Sb—Te—N layer, a (an element in Group 5A)-Sb—Te—N layer, a (an element in Group 6A)-Sb—Te—N layer, (an element in Group 5A)-Sb—Se—N layer and an (an element in Group 6A)-Sb—Se—N layer, which are doped with nitrogen.

12. The phase change memory device of claim 10, wherein the upper layer portion is an undoped chalcogenide material layer.

13. The phase change memory device of claim 9, wherein the crystal lattice of the lower layer portion is face-centered cubic (FCC) crystal lattice.

14. The phase change memory device of claim 13, wherein the crystal lattice of the upper layer portion is hexagonal close-packed (HCP) crystal lattice.

15. The phase change memory device of claim 9, wherein the crystal lattice of the upper layer portion is hexagonal close-packed (HCP) crystal lattice.

16. The phase change memory device of claim 9, wherein the upper layer portion is an undoped chalcogenide material layer.

17. The phase change memory device of claim 16, wherein the upper layer portion is one selected from the group consisting of a Ge—Sb—Te layer, an As—Sb—Te layer, an As—Ge—Sb—Te layer, an Sn—Sb—Te layer, a (an element in Group 5A)-Sb—Te layer, a (an element in Group 6A)-Sb—Te layer, (an element in Group 5A)-Sb—Se layer and an (an element in Group 6A)-Sb—Se layer.

18. The phase change memory device of claim 9, wherein the upper stack includes an adhesive layer and a top electrode which are deposited sequentially.

19. A method of forming a phase change material layer, the method comprising:
forming a doped lower layer by supplying a first source material and a doping gas onto a substrate;
stopping supply of the doping gas; and
forming an undoped upper layer by supplying a second source material onto the lower layer; wherein
crystal lattices of the formed undoped upper layer and doped lower layer are different.

20. The method of claim 19, wherein the first and second source materials are the same.

21. The method of claim 19, wherein the doped lower layer and the undoped upper layer are formed of a chalcogenide material layer.

22. The method of claim 19, wherein the undoped upper layer and the doped lower layer are formed at a temperature for forming crystalline crystal lattices.

23. The method of claim 19, wherein the undoped upper layer and the doped lower layer are formed between about 250° C. and about 400° C., inclusive.

24. The method of claim 19, wherein the undoped upper layer and the doped lower layer are formed at different temperatures.

25. The method of claim 19, wherein the first and second source materials are different.

26. The method of claim 19, wherein the crystal lattice of the undoped upper layer is hexagonal close-packed (HCP) crystal lattice.

27. The method of claim 26, wherein the crystal lattice of the doped lower layer is face-centered cubic (FCC) crystal lattice.

28. The method of claim 19, wherein the crystal lattice of the doped lower layer is face-centered cubic (FCC) crystal lattice.

29. The method of claim 19, wherein the forming of the doped lower layer and the forming of the undoped upper layer are performed in-situ.

30. A method of manufacturing a phase change memory device, the method comprising:
forming a storage node by sequentially forming a lower stack, a phase change material layer and an upper stack; wherein
the phase change material layer is formed according to the method of claim 19.

31. The method of claim 30, wherein the first and second sources are the same.

32. The method of claim 30, wherein the doped lower layer and the undoped upper layer are formed of a chalcogenide material layer.

33. The method of claim 30, wherein the undoped upper layer and the doped lower layer are formed at about 250° C. to about 400° C., inclusive.

34. The method of claim 30, wherein the undoped upper layer and the doped lower layer are formed at different temperatures.

35. The method of claim 30, wherein the first and second sources are different from each other.

36. The method of claim 30, wherein the crystal lattice of the undoped upper layer is hexagonal close-packed (HCP) crystal lattice.

37. The method of claim 36, wherein the crystal lattice of the doped lower layer is face-centered cubic (FCC) crystal lattice.

38. The method of claim 30, wherein the crystal lattice of the doped lower layer is face-centered cubic (FCC) crystal lattice.

39. The method of claim 30, wherein the forming of the doped lower layer and the forming of an undoped upper layer are performed in-situ.

40. The method of claim 30, wherein the upper stack is formed by sequentially depositing an adhesive layer and a top electrode.

41. A phase change memory device comprising:
a switching device; and
a storage node connected to the switching device; the storage node including,
a lower stack,
a phase change material layer,
a diffusion suppression film, and
an upper stack, the lower stack, the phase change material layer, the diffusion suppression film and the upper stack being sequentially deposited, wherein
the diffusion suppression film is an undoped phase change material film, and a crystal lattice of the diffusion suppression film is different from a crystal lattice of the phase change material layer.

42. The phase change memory device of claim 41, wherein the phase change material layer and the diffusion suppression film are formed of a chalcogenide material.

43. The phase change memory device of claim 41, wherein the crystal lattice of the phase change material layer is face-centered cubic (FCC) crystal lattice and the crystal lattice of the diffusion suppression film is hexagonal close-packed (HCP) crystal lattice.

44. The phase change memory device of claim 41, wherein the upper stack includes an adhesive layer and a top electrode deposited sequentially.

45. A method of manufacturing a phase change memory device, the method comprising:
forming a storage node by sequentially forming a lower stack, a phase change material layer, a diffusion suppression film and an upper stack; wherein
the diffusion suppression film is formed of an undoped phase change material film and formed to have a crystal lattice different from a crystal lattice of the phase change material layer.

46. The method of claim 45, wherein the phase change material layer and the diffusion suppression film are formed of a chalcogenide material.

47. The method of claim 45, wherein the phase change material layer and the diffusion prevention film are formed at about 250° C. to about 400° C., inclusive.

48. The method of claim 45, wherein the phase change material layer and the diffusion suppression film are formed at different temperatures.

49. The method of claim 45, wherein the crystal lattice of the phase change material layer is face-centered cubic (FCC) crystal lattice.

50. The method of claim 49, wherein the crystal lattice of the diffusion prevention film is hexagonal close-packed (HCP) crystal lattice.

51. The method of claim 45, wherein the crystal lattice of the diffusion prevention film is hexagonal close-packed (HCP) crystal lattice.

52. The method of claim 45, wherein the upper stack is formed by sequentially depositing an adhesive layer and a top electrode.
